(19) United States
(12) Patent Application Publication
(10) Pub. No.: US 2011/0232717 A1
(43) Pub. Date: Sep. 29, 2011

(54) SEMICONDUCTORS COMPOSITIONS FOR DYE-SENSITIZED SOLAR CELLS

(75) Inventors: John C. Warner, Wilmington, MA (US); Helen Van Benschoten, Wakefield, MA (US); Amy Cannon, Wilmington, MA (US)

(73) Assignees: OneSun, LLC, Sausalito, CA (US); Warner Babcock Institute for Green Chemistry, Wilmington, MA (US)

(21) Appl. No.: 13/030,062

(22) Filed: Feb. 17, 2011

Related U.S. Application Data
(60) Provisional application No. 61/305,861, filed on Feb. 18, 2010.
(60) Provisional application No. 61/305,899, filed on Feb. 18, 2010.
(60) Provisional application No. 61/305,908, filed on Feb. 18, 2010.
(60) Provisional application No. 61/305,911, filed on Feb. 18, 2010.

(51) Int. Cl. H01L 51/46; H01L 31/18; C08G 83/00; C07F 7/28; H01L 31/042

(52) U.S. Cl. 136/244; 438/4; 525/50; 556/51; 428/402; 136/263; 257/E31.032

(57) ABSTRACT

The present application discloses compositions for thin film dye-sensitized solar cells in which nanoparticles of semiconductor material are tethered together in a nanonodular network using a multi-functional linking compound.

### CROSS-REFERENCE TO RELATED APPLICATIONS

This application claims priority to U.S. Provisional Application No. 61/305,861, filed Feb. 18, 2010 and entitled, “SEMICONDUCTOR ADDITIVES FOR ELECTRON CHANNELING” [WBI 24.004]; U.S. Provisional Application No. 61/305,899, filed Feb. 18, 2010 and entitled, “COMPOSITION OF MATTER FOR SOLAR CELLS” [WBI 24.006]; U.S. Provisional Application No. 61/305,908, filed Feb. 18, 2010 and entitled, “NANONODULARITY FOR SEMICONDUCTORS IN SOLAR CELLS” [WBI 24.007]; and U.S. Provisional Application No. 61/305,911, filed Feb. 18, 2010 and entitled, “ROOM TEMPERATURE COALESCENCE OF METAL OXIDES FOR SOLAR CELLS” [WBI 24.008], the disclosures of which are hereby incorporated herein by reference.

Further, this application is related to Attorney Docket No. ONEP.P0024US entitled, “ADDITIVES FOR SOLAR CELL SEMICONDUCTORS”; and Attorney Docket No. ONEP.P0025US entitled, “SYSTEMS AND METHODS FOR PREPARING COMPONENTS OF PHOTOVOLTAIC CELLS,” both filed concurrently herewith and the disclosures of which are hereby incorporated herein by reference.

### TECHNICAL FIELD

The present disclosure relates to dye-sensitized solar cells, and particularly, to semiconductor compositions for use in dye-sensitized solar cells.

### BACKGROUND OF THE INVENTION

The availability of affordable sources of energy is critical to the modern way of life. Activities concerning all types of businesses, manufacturing, transportation etc. require energy in one form or another. The primary source of energy in the United States and many other countries is fossil fuels such as, coal, oil and natural gas. Fossil fuels, however, are non-renewable sources of energy (i.e., energy sources that cannot be recreated by man). Furthermore, the burning of fossil fuels for energy produces carbon dioxide, which is a greenhouse gas. Excessive amounts of greenhouse gases cause unusual warming of the earth's atmosphere, the greenhouse effect, which is a significant environmental concern. Furthermore, the demand for energy worldwide is increasing. There is a need, therefore, for the development of sustainable and affordable renewable sources of energy that are environmentally friendly (i.e., a “green” alternative).

Solar energy, although not strictly renewable, is virtually unlimited, and therefore provides a promising, green alternative energy source. One way to harness solar energy is through the use of solar cells, which convert light into electricity through the photovoltaic effect. In particular, thin film solar cells, such as the dye-sensitized solar cell (“DSSC”) offer a promising energy source because, when compared to traditional silicon wafer based cells, thin films are generally lower cost and allow the use of different materials. There is a need to develop materials that will enable DSSC's to function as intended (i.e., contribute to the efficient conversion of light into energy), while also maintaining their status as a green alternative (i.e., limited or no environmental or health impact).

Nano-scale materials may be useful in solar cell applications. Although a promising field of technology, there still remains much to be learned about the effect nanoparticles may have on the environment and living creatures. The lack of data regarding such effects has raised some concern in the scientific community. Thus, there remains a need to develop a way to use nanoparticles in solar cells while also reducing the risk of adverse environmental or health effects.

### BRIEF SUMMARY OF THE INVENTION

The present application discloses a semiconductor composition for use in a solar cell, such as a thin film dye-sensitized solar cell. More particularly, embodiments are disclosed in which nanoparticles of semiconductor material are tethered together in a nanonodular network via a multi-functional organic linking compound. The tethered molecules form a nanonodular network of immobilized nanoparticles, thus limiting or preventing the nanoparticles from becoming airborne and limiting or preventing adverse environmental or health risks potentially associated with airborne nanoparticles.

In various embodiments, the nanoparticles include organic, inorganic, and organometallic compounds. For example, the nanoparticles may include a single metal oxide, a binary metal oxide, a ternary metal oxide, and/or a quaternary metal oxide. Further, for example, the nanoparticles may be oxides such as an aluminum oxide, a barium titanate, a calcium titanate, a hafnium oxide, a hydroxyapatite, a magnesium oxide, a manganese oxide, a silicon oxide, a tin oxide, a titanium oxide, a zirconium oxide, and a zinc oxide.

In various embodiments, the linking compound has a plurality of functional groups. Each functional group may, for example, serve as a bonding site for semiconductor material, such as the metal oxides listed above. Exemplary linking compounds and functional groups include a carboxylic acid, a sulfonic acid, a phosphonic acid, a siloxane, a phenol, a derivative of acetylacetonate, and a combination thereof. Additional exemplary linkers include terephthalic acid, trimesic acid, or phenylflourone. In various embodiments, the bond between each of the nanoparticles and each of the functional groups of the linking compound may be a reversible covalent bond, an irreversible covalent bond, or an ionic bond. In various embodiments, the reversible bond may be formed between the nanoparticles and a disulfide, a Schiff-base, a thioester, or a boronate ester.

In various embodiments, the linking compound includes a biodegradable polymer, a non-biodegradable polymer, a material that degrades under ultraviolet (UV) radiation, or a material resistant to degradation by ultraviolet radiation. Using a UV degradable material may, for example, help facilitate the making of a “green” alternative semiconductor. For example, a UV degradable linker may be separated or degraded without compromising the integrity or function of other semiconductor components, which may then be used in a new application or in the same application by combining the isolated semiconductor particles with a linker to regenerate the semiconductor.

The foregoing has outlined rather broadly the features and technical advantages of the present invention in order that the detailed description of the invention that follows may be better understood. Additional features and advantages of the invention will be described hereinafter which form the subject of the claims of the invention. It should be appreciated by those skilled in the art that the conception and specific embodiment disclosed may be readily utilized as a basis for modifying or designing other structures for carrying out the same purposes of the present invention. It should also be realized by those skilled in the art that such equivalent constructions do not depart from the spirit and scope of the invention as set forth in the appended claims. The novel features which are believed to be characteristic of the invention, both as to its organization and method of operation, together with further objects and advantages will be better understood from the following description when considered in connection with the accompanying figures. It is to be expressly understood, however, that each of the figures is provided for the purpose of illustration and description only and is not intended as a definition of the limits of the present invention.

### BRIEF DESCRIPTION OF THE DRAWINGS

For a more complete understanding of the present invention, reference is now made to the following descriptions taken in conjunction with the accompanying drawings, in which:

FIG. 1 shows an exemplary embodiment of a linking compound;

FIG. 2 shows an exemplary embodiment of a linking compound bonded to nanoparticles of a semiconductor;

FIG. 3A shows an exemplary embodiment of a nanonodular network;

FIG. 3B shows the molecular structure of benzoic acid;

FIG. 3C shows the molecular structure of an exemplary embodiment of a linking compound, trimesic acid;

FIG. 4 illustrates a method of recycling semiconductor nanoparticles;

FIG. 5 is a cross-sectional view of an exemplary embodiment of a dye-sensitized solar cell including a nanonodular semiconductor composition according to the present disclosure;

FIG. 6 depicts the operation principal of an exemplary embodiment of a dye-sensitized solar cell including a nanonodular semiconductor composition according to the present disclosure;

FIG. 7 shows an exemplary embodiment of a solar panel including a nanonodular semiconductor composition according to the present disclosure;

FIG. 8A shows an exemplary embodiment of a support structure for a solar panel;

FIG. 8B depicts a cross-sectional view of an exemplary embodiment of the flow of electrical energy between neighboring solar cells;

FIG. 9 shows an exemplary embodiment of a dye-sensitized solar cell incorporated into a solar-ready commercial rooftop;

FIG. 10 depicts the current-voltage character of a dye-sensitized solar cell without trimesic acid; and

FIG. 11 depicts the current-voltage character of a dye-sensitized solar cell with trimesic acid.

### DETAILED DESCRIPTION OF THE INVENTION

The present application discloses a semiconductor composition for use in a solar cell, such as a thin film dye-sensitized solar cell. More particularly, there is disclosed a semiconductor composition including nanoparticles of semiconductor material tethered together using a multi-functional organic linking compound. The tethered molecules form a nanonodular network of immobilized nanoparticles, thus limiting or preventing the nanoparticles from becoming airborne and limiting or preventing adverse environmental or health risks potentially associated with airborne nanoparticles.

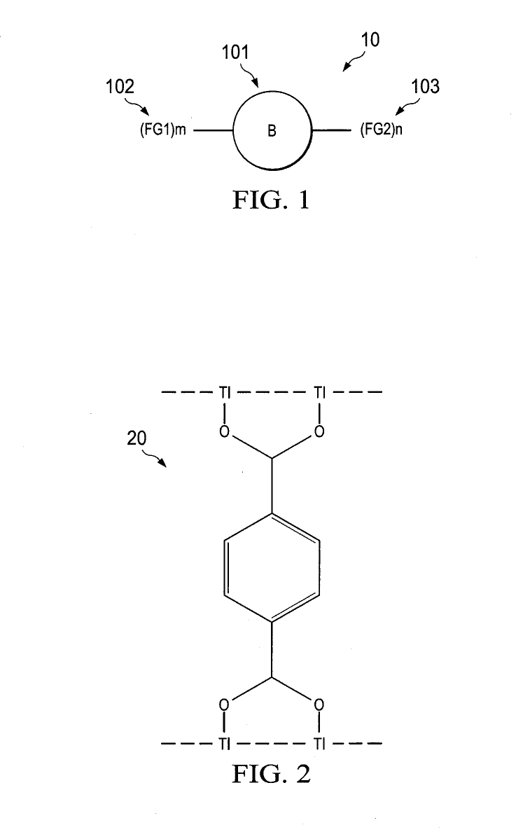

In an exemplary embodiment of the present invention, a nanonodule is formed by tethering semiconductor nanoparticles together using an organic linking compound. For example, as illustrated in FIG. 1, linking compound 10 may include a backbone (“B”) 101 and functional groups, for example, independent first functional group (“FG1”) 102 and independent second functional group (“FG2”) 103. In various embodiments, the linking compound may include a plurality of first functional group 102, a plurality of second functional group 103, or a combination thereof, the number of which is denoted by the symbols “m” and “n.” For example, “m” and “n” may individually be an integer of 1, 2, or 3. The nanonodule is formed by bonding semiconductor nanoparticles, such as titanium dioxide or nanoparticles of other suitable oxides listed herein, to a linking compound (such as linking compound 10) at each functional group (such as first functional group 102 and second functional group 103). An exemplary nanonodule bonding scheme is illustrated in FIG. 2. FIG. 2 illustrates a nanonodule 20, in which titania nanoparticles are tethered together by a linking compound, terephthalic acid.

Various materials may be used as the nanoparticles of the nanonodules described above. For example, a single, a binary, a ternary, or a quaternary metal oxide compound may be used. Exemplary metal oxide compounds include barium titanate, calcium titanate, hafnium oxides, magnesium oxides, manganese oxides, tin oxides, titanium oxides (e.g., titanium dioxide), zinc oxides, and zirconium oxides. Other oxide compounds, such as hydroxyapatite and silicon oxides, may also be used. In addition, additives or insulating particles may be incorporated to improve the performance of the semiconductor, and thus, efficiency of the solar cell. Additional exemplary semiconductor compositions and structures are shown and described in the patent application entitled, “ADDITIVES FOR SOLAR CELL SEMICONDUCTORS” (Attorney Docket No. ONEP.P0024US), filed concurrently herewith, and incorporated herein by reference.

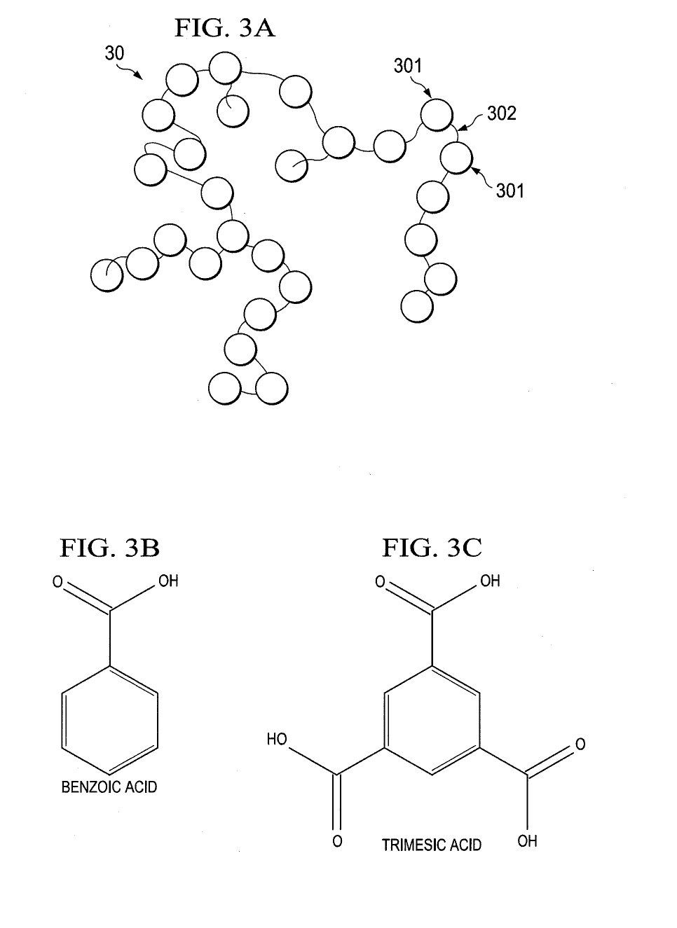

In an exemplary embodiment, an aggregate of nanonodules forms a nanonodular polymer network in which the nanoparticles are essentially immobilized, that is, the nanoparticles are less likely to become airborne than in a semiconductor without the organic linker. The resulting average particle diameter in the nanonodular network may be, for example, between 1.0 micrometers and 1,000 micrometers. In various embodiments, as illustrated in the examples 1 through 3 contained herein, the addition of a linking compound does not reduce the effectiveness (i.e., conversion efficiency) of the solar cell. An exemplary nanonodular network 30 and bonding scheme is illustrated in FIG. 3A. In FIG. 3A, nanoparticles (such as nanoparticle 301) are represented by spherical elements, and linking compounds (such as linking compound 302) are represented by lines.

In general, the linking compound used to create a nanonodular network may be selected, and thus, the properties of a semiconductor fine-tuned for a particular application, based on various factors. These factors include size ratio between nanoparticles and linking compounds, rigidity or flexibility of linking compounds, and whether hydrophobicity is a desired characteristic. Further, for example, a linking compound may be selected based on the nature of the bond between nanoparticles and the linking compound. In various embodiments according to the present disclosure, a strong or irreversible covalent bond may be desired. In other embodiments, a reversible bond (covalent or ionic) may be desired, that is, a bond that can be more readily broken or cleaved under appropriate conditions. Exemplary reversible covalent bonds include disulfides, Schiff-bases, thioesters, boronate esters, and the like. In one aspect, the irreversible bond is cleaved under conditions that do not adversely affect the nanoparticles.

Further, a linking compound may be selected based on its ability to decompose or not decompose under certain conditions. In various embodiments, the linking compound may exhibit non-biodegradable or biodegradable characteristics. In other embodiments, the linking compound may be resistant to degradation by ultraviolet radiation (“UV”). In another embodiment, the linking compound may be UV sensitive. Thus, for example, a UV sensitive linker may be intentionally decomposed or otherwise removed at the end of the useful life of the semiconductor to isolate and recycle still useful nanoparticles (e.g., a metal oxide).

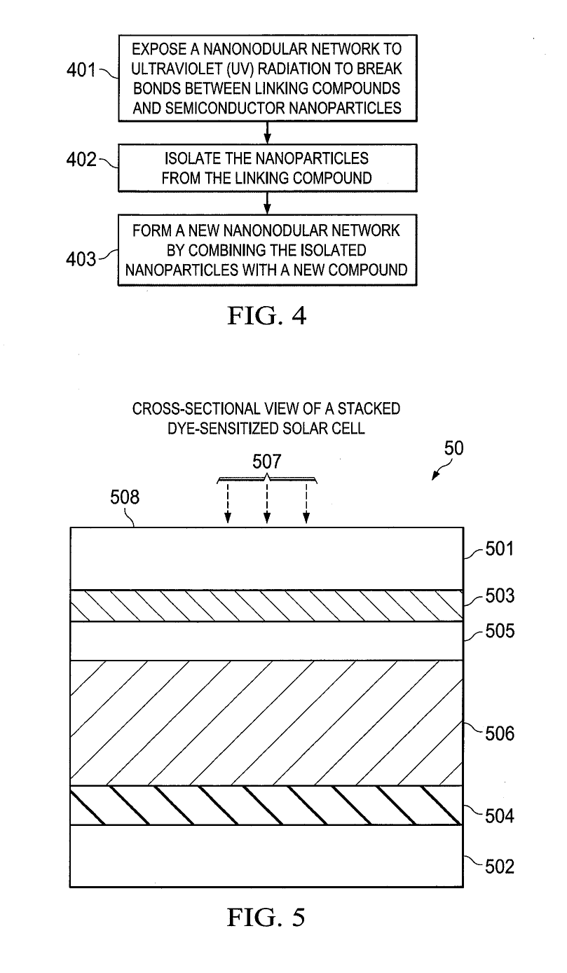

A method of recycling or regenerating a semiconductor is described in FIG. 4. At step 401, a nanonodular network is exposed to a ultraviolet radiation (e.g., irradiated in an oxygen-rich atmosphere) to break bonds between a linking compound and semiconductor nanoparticles. The nanoparticles are then isolated from the linking compound at step 402. At step 403, the nanoparticles are recycled. That is, a new nanonodular network is formed by combining or re-tethering the isolated semiconductor nanoparticles with a new linking compound so it may be used in a solar cell.

The linking compound, that is, the material used to bond nanoparticles to form a nanonodular network, is a multi-functional organic compound. Multi-functional, rather than mono-functional compounds, are used as the linking molecule because their multiple bonding sites facilitate the bonding of multiple molecules, and thus, the formation of a network, i.e., a nanonodular network. This phenomenon is demonstrated in examples 1 and 2 below. An exemplary multi-functional linker is carboxylic acid because it adsorbs on the surface of metal oxide, such as titanium dioxide. Thus, multi-functional carboxylic acids such as terephthalic acid (1,4-Benzenedicarboxylic acid) and trimesic acid (1,3,5-Benzenetricarboxylic acid), shown at FIG. 3C, may be incorporated into a semiconductor as a linking compound. Other suitable functional groups or multi-functional compounds include sulfonic acid, phosphonic acid, siloxane, phenol, and ligands, such as phenylfluorone and derivatives of acetylacetonate. Further, disulfides, Schiff-bases, thioesters, boronate esters, and the like may be suitable functional groups for forming nanoparticle links. Combinations of any of the above functional groups and compounds may be utilized.

Nanonodules, such as illustrated in FIGS. 1 through 3A above, are incorporated into a semiconductor film for use in a solar cell. An exemplary embodiment of a semiconductor film may be prepared by mixing particles of semiconductor material (such as nanoparticles of titanium dioxide) in a slurry and then depositing the slurring on a substrate. In various embodiments, the substrate may be an indium tin oxide substrate. The semiconductor film may be formed without sintering. That is, neither the film, nor the assembled device is exposed to temperatures above 150° C. (typically, a sintering temperature is in the range of 300° C. to 500° C., for example 450° C.). For more information regarding ambient temperature coalescence of metal oxides for solar cells, see the patent application entitled, “SYSTEMS AND METHODS FOR PREPARING COMPONENTS OF PHOTOVOLTAIC CELLS” (Attorney Docket No. ONEP.P0025US), filed concurrently herewith, and incorporated herein by reference.

FIG. 5 is a cross-sectional view of an exemplary embodiment of a dye-sensitized solar cell 50. The components of solar cell 50 may be stacked, or vertically oriented, to accept incident light 507 at top surface 508. Solar cell 50 of the illustrated embodiment includes anode 503, nanonodular semiconductor 505 coated with a photo-sensitive dye, electrolyte 506, cathode 504, superstrate 501, and substrate 502. In the illustrated embodiment, anode 503 is interfaced with nanonodular semiconductor 505 and superstrate 501; semiconductor 505 is interfaced with electrolyte 506; electrolyte 506 is interfaced with cathode 504; and cathode 504 is interfaced with substrate 502. Components of solar cell 50 are not drawn to scale and are not intended to show relative dimensions of each layer.

In various embodiments, superstrate 501 may be clear or transparent to allow light to pass through and may include one or more of the following materials: poly(methyl methacrylate) (also called PMMA) and poly(ethylene terephthalate) (also called PET). Substrate 502 may include, for example, PET. Further, anode 503 and cathode 504 may be made of material such as silver, copper, aluminum, nickel, gold, platinum, carbon, conductive polymers, carbon nanotubes, graphene, and combinations thereof. A photo-sensitive dye may be organic or organometallic dye impregnated or adsorbed on the semiconductor material. Exemplary dyes include ruthenium bipyridyl dicarboxylate dye (also called N3) and other chromophores containing carboxylic acids or functional groups capable of binding to titanium dioxide. Further, an exemplary electrolyte includes a liquid iodide-triiodide (I₃⁻/I⁻) redox couple or other suitable electrolytes capable of regenerating the photo-oxidized dye.

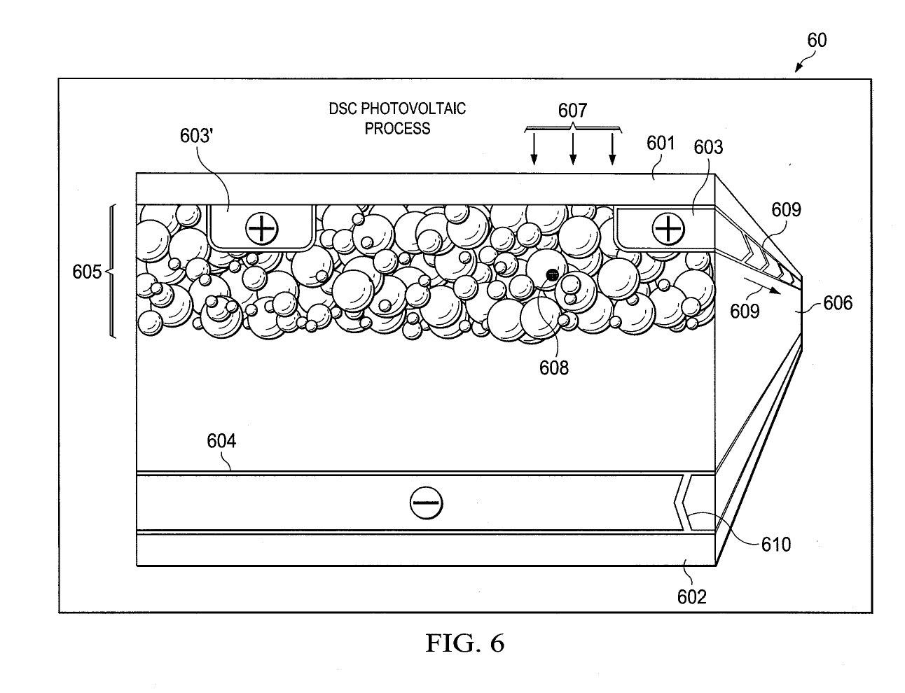

FIG. 6 is a schematic representation of a dye-sensitized solar cell, such as solar cell 50 of FIG. 5, in operation. Incident light 607 strikes solar cell 60, passing through superstrate 601, further passing through open areas of patterned anode portions 603, 603′, and interacting with photo-sensitive dye (i.e., a chromophore) adsorbed on metal oxide particles of semiconductor 605. As a result, electrons, such as electron 608, are released or injected into semiconductor 605. Exemplary electron 608 traverses the metal oxide network of semiconductor 605 to reach anode 603, 603′ and then exits solar cell 60. The resulting oxidized dye is regenerated by electrolyte 606. Electrolyte 606 is, in turn, regenerated at cathode 604 to complete the electric circuit. The general flow of electrons is roughly illustrated by arrows 609 and 610. Additionally, solar cell 60 may have a bottom support or substrate 602.

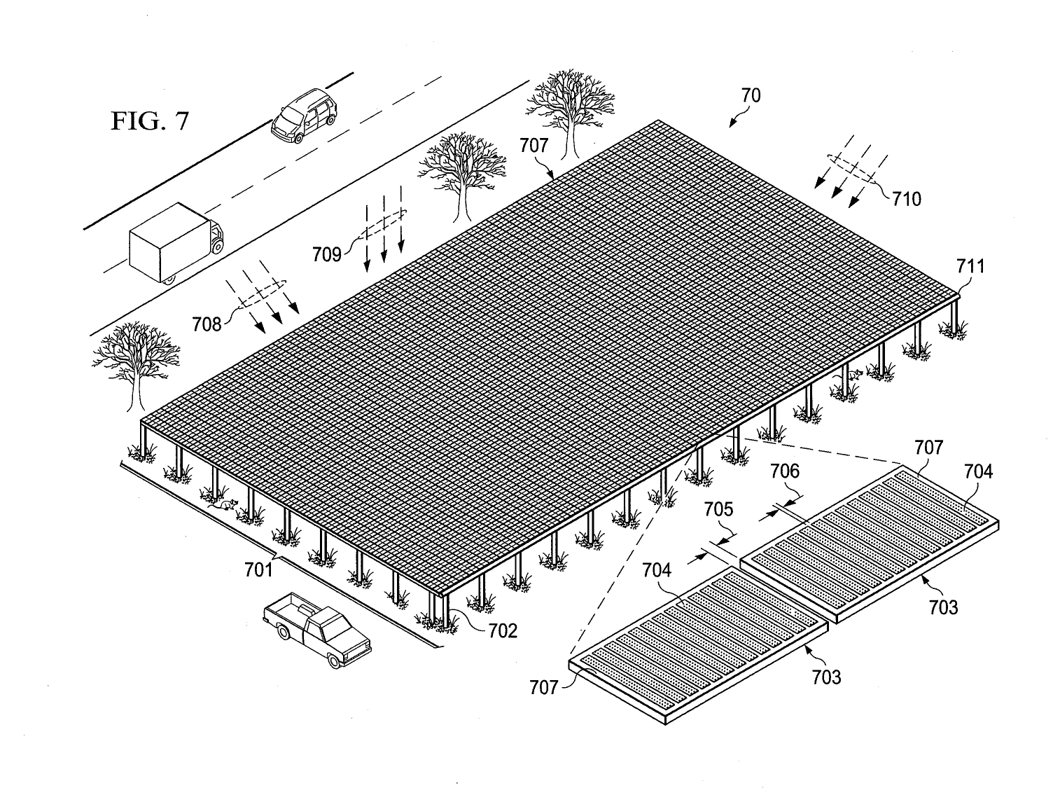

Further, exemplary embodiments of a dye-sensitized solar cell with a nanonodular network, such as solar cells 50 and 60 described in FIGS. 5 and 6, respectively, may be incorporated into a network to produce energy. Exemplary embodiments of a network of solar cells having a nanonodular network are illustrated in FIGS. 7, 8A, 8B, and 9.

FIG. 7 illustrates a solar panel 70 including an arrangement of solar cells 704 within modules 703. In the illustrated embodiment, modules 703 have a substantially planar top surface 707 for receiving incident light 708, 709, 710 at various angles. Top surface 707 lie in the same plane as top surfaces of neighboring modules to form a solar panel 70 that has a substantially horizontal orientation.

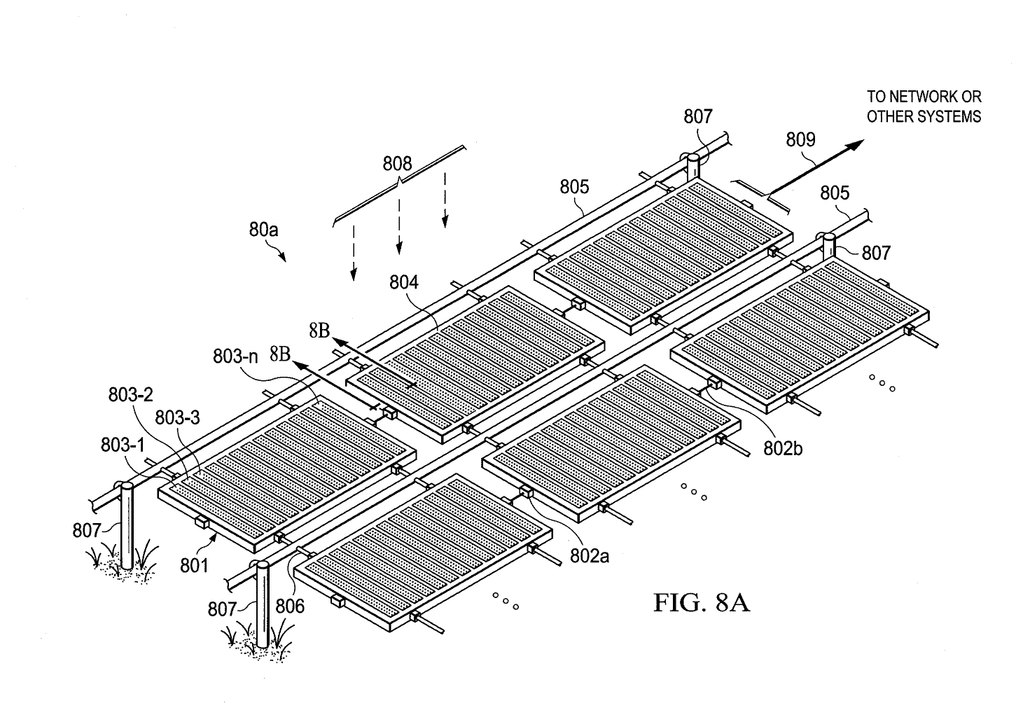

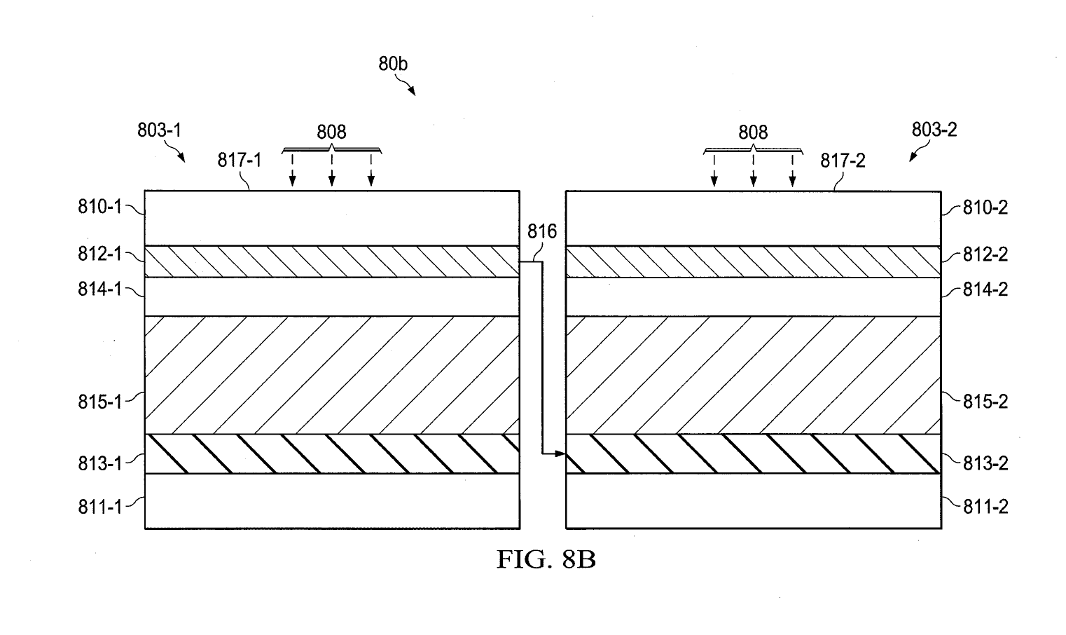

Each solar cell 704 and module 703 (and solar cells 803-1 to 803-n and modules 801, discussed infra) may be of various shapes, dimensions, or patterns, and of uniform or non-uniform shape, dimension, or pattern with respect to other modules or solar cells. In the illustrated embodiment, modules 703 and solar cells 704 are rectangular and parallel with respect to other solar cells in the same module. In one embodiment, each module 703 has a length of about 50 inches and a width of about 30 inches, and each solar cell 704 has a width equal to or less than 30 inches and a length of about 1 3/16 inches. Each solar cell 704 may be electrically connected in series to a neighboring solar cell 704 (see, for example, FIG. 8B). Further, solar cells 704 may be separated by a predetermined distance 706 from neighboring solar cells, and modules 703 may be separated by predetermined distances 705 from neighboring modules. In the space between solar cells 704, such as predetermined distance 705, a bus bar may be situated and electrically connected to solar cells 704 to aid in capturing electrical energy.

In one embodiment, solar panel 70 may be elevated off the ground or other surface with support structure 701. Support structure 701 may include a frame, where the frame is formed of beams, such as beam 711. Support cables, as illustrated in FIG. 8A, may also be used to support or stabilize modules 703. Such support cables may be attached to a frame, such as formed from beams 711, or directly to posts 702. Further, in the illustrated embodiment, posts 702 are used to support the frame and solar panel 70. In one embodiment, posts 702 do not extend above the plane of module surface 707, thereby eliminating potential shading or blocking of incident light. Further, the height of elevation for solar panel 70 may be selected to permit human, vehicular, or robotic access to interior modules 703 for cleaning, maintenance, or replacement, to allow maintenance of grounds beneath solar panel 70, or to allow wild life to roam freely without interfering with solar panel 70 (and minimally interfering with the ability of wild life to freely roam). The energy produced by modules 703 may be used locally, for example to power a local device or structure (not shown), or optionally transported along connected electrical lines (not shown) to a power distribution network for distribution and use elsewhere, such as with a utility grid.

FIG. 8A illustrates an exemplary embodiment of a solar panel support structure 80a. In the exemplary embodiment illustrated in FIG. 8A, array of modules 801, including plurality of solar cells 803-1 to 803-n, are held in position to receive incident light 808 by support structure 80a. In this embodiment, support structure 80a includes tensioned wires or support cables 805. Support cables 805 may, as illustrated, run coextensive with the horizontal plane (i.e., module surfaces 804) of modules 801. Support cables 805 are supported by posts 807. Posts 807 and support cables 805 also provide elevation to array of modules 801 to achieve, for example, those advantages of elevation described for FIG. 7. Further, modules 801 are connected to support cables 805 by one or more support connectors 806.

FIGS. 8A and 8B illustrate an exemplary embodiment of the flow of electricity between modules and solar cells, respectively. In the embodiment illustrated in FIG. 8A, modules 801 are connected in series such that the output of one module 801 is the input of an adjacent module via electrical connectors 802a and electrical cables 802b. Electrical energy produced at modules 801 follows path 809 for collection and/or distribution to a structure, network, or other system. In the embodiment illustrated in FIG. 8B, the flow of electricity within module 801 and among solar cells 803-1 to 803-n is shown. Depicted is a cross-sectional view 80b of neighboring solar cells 803-1 and 803-2 receiving incident light 808 at solar cell surfaces 817-1 and 817-2, respectively. Solar cells 803-1 and 803-2 each respectively include superstrates 810-1 and 810-2, anodes 812-1 and 812-2, semiconductors 814-1 and 814-2, electrolytes 815-1 and 815-2, cathodes 813-1 and 813-2, and substrates 811-1 and 811-2. Electrical path 816 demonstrates the flow of electrical energy from anode 812-1 of solar cell 803-1 to cathode 813-2 of solar cell 803-2. This transfer of electricity continues to the next solar cell of module 801 until reaching solar cell 803-n, and then exiting the module via electrical connector 802a and electrical cable 802b (illustrated in FIG. 8A).

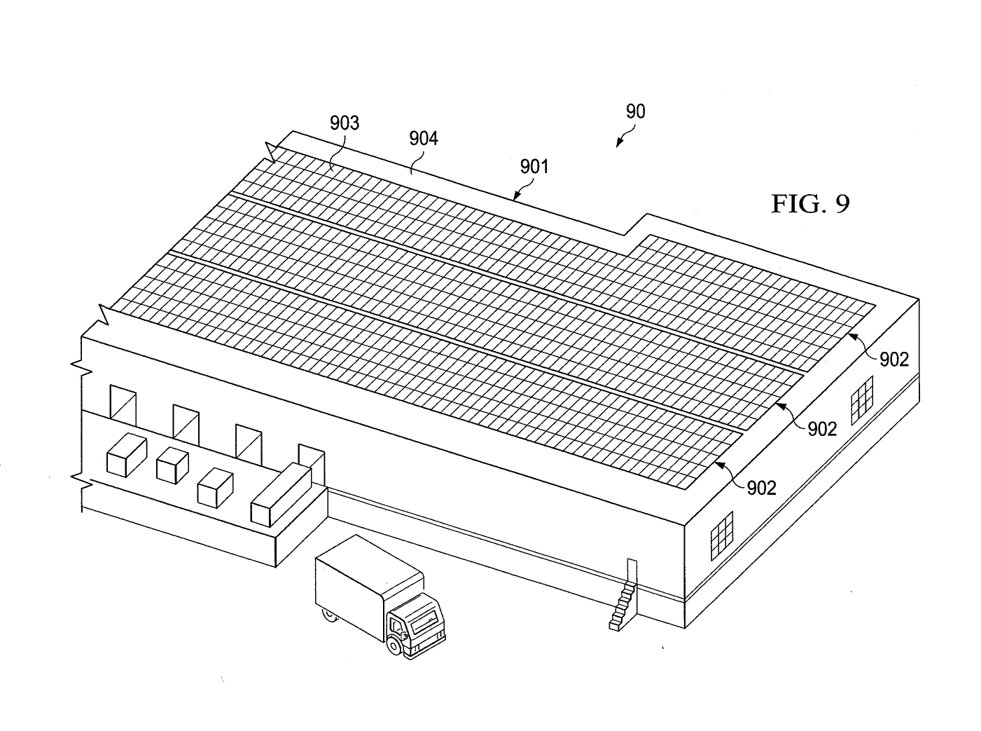

FIG. 9 illustrates another exemplary embodiment of a dye-sensitized solar cell incorporated into a network to produce energy. In system 90, modules 903 may be incorporated into a solar-ready commercial rooftop 904 of commercial building 901. Although a substantially rectangular commercial rooftop 904 is shown, those of skill in the art will appreciate that the rooftop may be a variety of shapes or dimensions, of non-uniform height, or may be incorporated into non-commercial rooftops. In exemplary system 90, each module 903 is spaced a predetermined distance from another module, and several modules are placed in an array to form panels 902. Each panel 902 of this embodiment has a substantially horizontal orientation for receiving incident light on the surface of modules 903.

Further, modules 903 may be each electrically connected to one another (for example, as described with reference to FIGS. 7, 8A, and 8B) and/or building's 901 electrical system by electrical connectors or terminal wires (not shown) and provide power for operations contained within building 901. Surplus power may optionally be directed to other local structures or to a power distribution network for distribution and use at other locations or facilities. The roof of the building may provide support for modules 903 or, alternatively, posts and tensioned wires or cables, such as described with reference to FIGS. 7 and 8A, may be incorporated to provide elevation to modules 903 and/or panels 902.

### EXAMPLES

The starting materials and reagents used in preparing compounds in the following examples may be acquired from commercial suppliers such as the Aldrich Chemical Co., Inc. (Milwaukee, Wis.), Bachem Americas, Inc. (Torrance, Calif.), Sigma-Aldrich Corp. (St. Louis, Mo.), may be prepared by methods known to a person of ordinary skill in the art, or may be prepared by following procedures such as those described in the following references: Organic Reactions (vols. 1-40, John Wiley & Sons, 1991); J. March, Advanced Organic Chemistry (John Wiley & Sons, 4th ed.); and Larock, Comprehensive Organic Transformations (VCH Publishers, 1989).

### Example 1

Particle size measurements for a nanonodular network. The following experiment was performed to demonstrate the formation of nanonodules. First, a dispersion of titanium dioxide nanoparticles was prepared by a sol-gel method. Titanium isopropoxide was added into a 0.075 M solution of nitric acid in deionized water. The dispersion was then hydrolysed by heating it to 80° C. for ten hours. The dispersion was then heated in a sealed pressure tube at 250° C. for twelve hours, which is the step by which porous nanocrystalline (primarily anatase) networks are formed. The resulting dispersion was then sonicated for ten minutes, diluted to approximately 2% solids with deionized water, and pressure filtered using a 200 nm Whatman® Nuclepore™ polycarbonate membrane filter. The filtrate (referred to below as titanium dioxide sol), which contained particles of less than 200 nm, was divided into three equal samples and then used to prepare the following.

Sample 1 was prepared by adding 1 ml of titanium dioxide sol to 20 ml of 0.01 M benzoic acid (a mono-carboxylic acid), shown at FIG. 3B, in a transparent vial. Sample 2 was prepared by adding 1 ml of titanium dioxide sol to 20 ml of 0.01 M trimesic acid (a tri-carboxylic acid), shown at FIG. 3C, in a transparent vial. Sample 3, a reference sample, was prepared by adding 1 ml of titanium dioxide sol to 20 ml of water in a transparent vial. Differences in the settling behavior between the three samples were observed almost immediately. The titanium dioxide particles in Sample 1 (benzoic acid) and Sample 3 (water) remained suspended in the solution (observed as a “cloudy” or translucent solution), while the titanium dioxide particles in Sample 2 (trimesic acid) began to settle at the bottom of the vial. After allowing the samples to rest for 24 hours, they were again observed for settling behavior. Sample 1 (benzoic acid) and Sample 3 (water) were stable translucent suspensions. Sample 2 (trimesic acid), in comparison, contained particles which had settled at the bottom of the vial with clear supernatant above.

It is known that, in the same solution, a larger particle will settle faster than a smaller particle. Thus, in Sample 2, the particle size must have been higher relative to Sample 1 or Sample 3. Hence, trimesic acid (a multi-functional carboxylic acid) caused the particle size to increase (i.e., form nanonodules), while water and benzoic acid (a mono-functional carboxylic acid) did not have such an effect. Therefore, the multi-functional carboxylic acid is a linking compound.

Further, the suspensions of Samples 1, 2, and 3, were each measured for particle size distribution using a Beckman Coulter Delsa™ Nano C Particle Analyzer. The results, presented below in TABLE 1 below, confirm that the particle size increased with the addition of trimesic acid, but remained relatively unchanged for benzoic acid (compared to water). Hence, trimesic acid is an effective linker, that is, it enables the formation of a nanonodular network.

TABLE 1
Mean particle size measurements.

| Sam- | | | Mean | Polydispersity |
|---|---|---|---|---|
| ple | Additives | Linker | particle size | Index |
| 1 | benzoic acid | No | 134 nm | 0.2232 |
| | and water | | | |
| 2 | trimesic acid | Yes | 3494 nm | 0.496 |
| | and water | | | |
| 3 | water | No | 141 nm | 0.236 |

### Example 2

Performance of a dye-sensitized solar cell having a semiconductor with a nanondular network. This example demonstrates that, in some embodiments, adding a linking compound to form a nanonodular network does not reduce the performance of the solar cell as it would otherwise be absent the linking compound.

Two titanium dioxide based slurries were prepared as follows. A first slurry was prepared by mixing titanium dioxide nanopowder (Evonik Degussa Corporation, Aeroxide® P25 (“P25”) having an average primary particle size of 21 nm) (about 37% by weight) with water (about 62% by weight) and Triton X-100 (octylphenol ethoxylate sold by the Dow Chemical Company) (about 0.6% by weight). To this mixture was added titanium dioxide nanoparticles synthesized by a sol-gel method (see EXAMPLE 1). A second slurry was prepared the same as the first slurry, except that trimesic acid was added at 0.3% by weight of the P25 TiO₂.

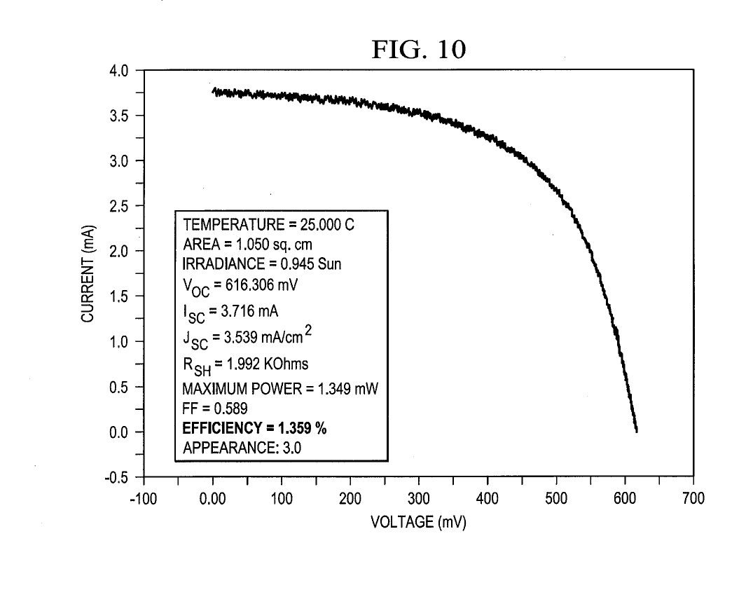

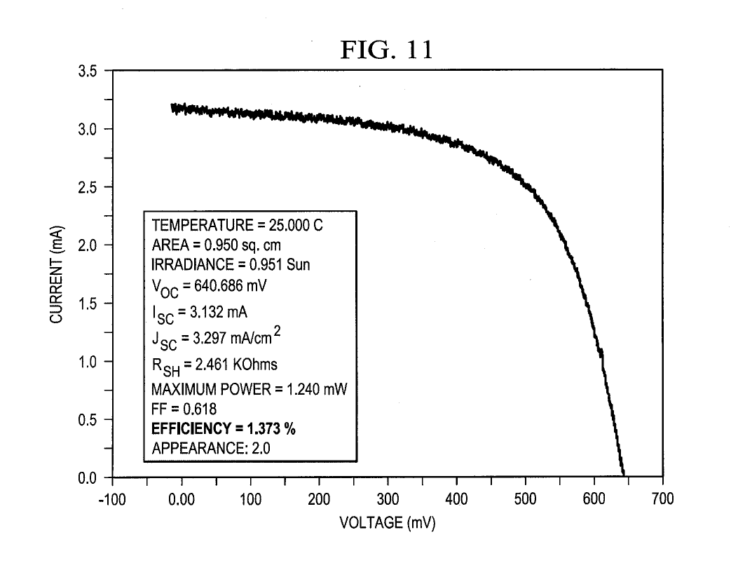

A layer of the first and second slurries were deposited on conductive glass, dried at 75° C., and then soaked in N3 dye. The thin film semiconductors were then incorporated into a stacked dye-sensitized solar cell. The current-voltage character for the dye-sensitized solar cell incorporating the first and second thin film semiconductors was measured. FIG. 10 depicts the current-voltage character of the dye-sensitized solar cell without trimesic acid (i.e., without a linking compound in the semiconductor). FIG. 11 depicts the current-voltage character of the dye-sensitized solar cell with the trimesic acid (i.e., with a linking compound in the semiconductor). The conversion efficiency of both dye-sensitized solar cells is about 1.4%. Hence, in various embodiments, adding a linking compound, such as trimesic acid, does not adversely affect cell performance.

Although the present invention and its advantages have been described in detail, it should be understood that various changes, substitutions and alterations can be made herein without departing from the spirit and scope of the invention as defined by the appended claims. Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

What is claimed is:

1. A semiconductor composition for a thin film dye-sensitized solar cell comprising:
a linking compound comprising:
a backbone; and
a plurality of functional groups each bonded to the backbone of the linking compound; and
a plurality of nanoparticles each bonded to the linking compound at each of the plurality of functional groups.

2. The semiconductor composition of claim 1 immobilized in a thin film.

3. The semiconductor composition of claim 1 wherein the nanoparticles comprise an organic compound.

4. The semiconductor composition of claim 1 where in the nanoparticles comprise an inorganic compound.

5. The semiconductor composition of claim 1 wherein the nanoparticles comprise an organometallic compound.

6. The semiconductor composition of claim 1 wherein the nanoparticles are selected from the group consisting of:
a single metal oxide, a binary metal oxide, a ternary metal oxide, and a quaternary metal oxide.

7. The semiconductor composition of claim 1 wherein the nanoparticles are oxides selected from the group consisting of:
an aluminum oxide, a barium titanate, a calcium titanate, a hafnium oxide, a hydroxyapatite, a magnesium oxide, a manganese oxide, a silicon oxide, a tin oxide, a titanium oxide, a zirconium oxide, and a zinc oxide.

8. The semiconductor composition of claim 1 wherein the functional groups are independently selected from the group consisting of:
a carboxylic acid, a sulfonic acid, a phosphonic acid, a siloxane, a phenol, a derivative of acetylacetonate, and a combination thereof.

9. The semiconductor composition of claim 1 wherein the linking compound comprises the formula:
(FG1)ₘ—(B)—(FG2)ₙ
wherein “B” is the backbone of the linking compound;
“FG1” is an independent first functional group bonded to the backbone of the linking compound;
“FG2” is an independent second functional group bonded to the backbone of the linking compound;
“m” is an integer of 1, 2, or 3; and
“n” is an integer of 1, 2, or 3.

10. The semiconductor composition of claim 1 wherein the linking compound comprises a biodegradable polymer.

11. The semiconductor composition of claim 1 wherein the linking compound comprises a non-biodegradable polymer.

12. The semiconductor composition of claim 1 wherein the linking compound comprises a material that degrades under ultraviolet radiation.

13. The semiconductor composition of claim 1 wherein the linking compound comprises a material resistant to degradation by ultraviolet radiation.

14. The semiconductor composition of claim 1 wherein the linking compound is terephthalic acid.

15. The semiconductor composition of claim 1 wherein the linking compound is trimesic acid.

16. The semiconductor composition of claim 1 wherein the linking compound is phenylflourone.

17. The semiconductor composition of claim 1 wherein the bond between each of the nanoparticles and each of the functional groups of the linking compound is a reversible covalent bond.

18. The semiconductor composition of claim 17 wherein the reversible covalent bond is formed between the nanoparticles and a disulfide, a Schiff-base, a thioester, or a boronate ester.

19. The semiconductor composition of claim 1 wherein the bond between each of the nanoparticles and each of the functional groups of the linking compound is an irreversible covalent bond.

20. The semiconductor composition of claim 1 wherein the bond between each of the nanoparticles and each of the functional groups of the linking compound is an ionic bond.

21. The semiconductor composition of claim 1 wherein the average particle diameter is about 1.0 micrometers to about 1,000 micrometers.

22. A dye-sensitized solar cell comprising:
an anode;
a cathode;
an electrolyte in electrical communication with the anode and the cathode;
a semiconductor composition in electrical communication with the anode;
a dye coated on the semiconductor composition; and
an indium tin oxide substrate coated with the semiconductor composition;
wherein the semiconductor composition comprises:
a linking compound comprising a plurality of functional groups; and
a plurality of nanoparticles each bonded to the linking compound at each of the plurality of functional groups.

23. The dye-sensitized solar cell of claim 22 wherein a multiplicity of the nanoparticles are immobilized in a nanonodular network by the linking compound.

24. The dye-sensitized solar cell of claim 22 wherein the nanoparticles are oxides selected from the group consisting of:
an aluminum oxide, a barium titanate, a calcium titanate, a hafnium oxide, a hydroxyapatite, a magnesium oxide, a manganese oxide, a silicon oxide, a tin oxide, a titanium oxide, a zirconium oxide, and a zinc oxide.

25. The dye-sensitized solar cell of claim 22 wherein the functional groups are independently selected from the group consisting of:
a carboxylic acid, a sulfonic acid, a phosphonic acid, a siloxane, a phenol, a derivative of acetylacetonate, and a combination thereof.

26. The dye-sensitized solar cell of claim 22 wherein the linking compound comprises the formula:
(FG1)ₘ—(B)—(FG2)ₙ
wherein “B” is the backbone of the linking compound;
“FG1” is an independent first functional group bonded to the backbone of the linking compound;
“FG2” is an independent second functional group bonded to the backbone of the linking compound;
“m” is an integer of 1, 2, or 3; and
“n” is an integer of 1, 2, or 3.

27. The dye-sensitized solar cell of claim 22 wherein the linking compound comprises a biodegradable polymer, a non-biodegradable polymer, a material resistant to ultraviolet radiation, or a material that degrades under ultraviolet radiation.

28. The dye-sensitized solar cell of claim 22 wherein the linking compound is selected from the group consisting of:
terephthalic acid, trimesic acid, and phenylflourone.

29. The dye-sensitized solar cell of claim 22 wherein the bond between each of the nanoparticles and each of the functional groups of the linking compound is a reversible covalent bond, an irreversible covalent bond, or an ionic bond.

30. The semiconductor composition of claim 41 wherein the reversible covalent bond is formed between the nanoparticles and a disulfide, a Schiff-base, a thioester, or a boronate ester.

31. The dye-sensitized solar cell of claim 22 wherein the nanonodular network has an average particle diameter of about 1.0 micrometers to about 1,000 micrometers.

32. A semiconductor composition for a thin film dye-sensitized solar cell comprising:
an organic linking compound comprising a plurality of functional groups;
a plurality of nanoparticles having a first average particle size; and
a nanonodule of a second average particle size formed by bonding the plurality of nanoparticles to the plurality of functional groups;
wherein the second average particle size is greater than the first average particle size.

33. A method of regenerating a thin film semiconductor for a dye-sensitized solar cell comprising:
exposing a semiconductor composition to ultraviolet radiation;
wherein the semiconductor composition comprises:
a linking compound degradable by ultraviolet radiation, the linking compound comprising a plurality of functional groups; and
a plurality of nanoparticles bonded to the linking compound at each of the functional groups; and
wherein exposing the semiconductor composition to ultraviolet radiation breaks the bonds between the nanoparticles and the functional groups;
isolating the nanoparticles from the linking compound; and
forming a nanonodule by combining the isolated nanoparticles with a new compound.

34. A method of converting solar energy, said method comprising:
exposing a solar cell to light and thereby producing electrical energy, said solar cell comprising:
an anode interfaced with a thin film semiconductor;
an electrolyte interfaced with the thin film semiconductor; and
a cathode interfaced with the electrolyte;
wherein the thin film semiconductor comprises:
a linking compound, said linking comprising a backbone; and a plurality of functional groups each bonded to the backbone of the linking compound;
and a plurality of nanoparticles each bonded to the linking compound at each of the plurality of functional groups; and
capturing said electrical energy.

35. A method of claim 34 further comprising electrically connecting an array of said solar cells to form a network of said solar cells for producing electrical energy for a utility grid.
